(19) United States
(12) Patent Application Publication
(10) Pub. No.: US 2023/0403923 A1
(43) Pub. Date: Dec. 14, 2023

(54) METHOD FOR PATTERNING QUANTUM DOT LAYER

(71) Applicant: BOE Technology Group Co., Ltd., Beijing (CN)

(72) Inventor: Xiaoyuan ZHANG, Beijing (CN)

(21) Appl. No.: 18/036,383

(22) PCT Filed: Dec. 16, 2020
(86) PCT No.: PCT/CN2020/136901

§ 371 Date: May 10, 2023

(51) Int. Cl. H10K 71/20; H10K 50/16

(52) U.S. Cl. CPC H10K 71/233; H10K 50/16

(57) ABSTRACT

A method for patterning a quantum dot layer comprises: forming, on a substrate (1), a front film layer and a sacrificial layer (5) which are stacked in sequence, wherein one of the sacrificial layer and the front film layer is hydrophilic, and the other of the sacrificial layer and the front film layer is hydrophobic; forming a photoresist (6) having a through hole on the sacrificial layer, wherein the through hole corresponds to a target region, and etching the sacrificial layer in the target region under the shielding of the photoresist; laying a quantum dot material, and curing the quantum dots material of the target region; and removing the remaining sacrificial layer and the photoresist, and forming a patterned quantum dot layer in the target region.

The present application is a National Stage of International Application No. PCT/CN2020/136901, filed on Dec. 16, 2020, which is hereby incorporated by reference in its entirety.

### FIELD

The present disclosure relates to the technical field of display, in particular to a method for patterning a quantum dot layer.

### BACKGROUND

Quantum dots (QDs), also known as semiconductor nanocrystals and semiconductor nanoparticles, refer to nanosolid materials that have sizes in the order of nanometers in three dimensions of space or are composed of QDs as basic units, and are aggregates of atoms and molecules on a nanoscale. A light-emitting diode based on the quantum dots is called a quantum dot light-emitting diode (QLED), and is a novel light-emitting device.

### SUMMARY

An embodiment of the present disclosure provides a method for patterning a quantum dot layer, including: sequentially forming a front film layer and a sacrificial layer, which are stacked, on a substrate; wherein one of the sacrificial layer and the front film layer is hydrophilic, and the other of the sacrificial layer and the front film layer is hydrophobic; forming a mask layer having a through hole on the sacrificial layer, wherein the through hole corresponds to a target region, and etching the sacrificial layer in the target region under the shielding of the mask layer; laying a quantum dot material, and curing quantum dots in the target region; and forming a patterned quantum dot layer in the target region by removing a remaining sacrificial layer.

Optionally, in the above method for patterning the quantum dot layer provided by the embodiment of the present disclosure, the forming the mask layer having the through hole on the sacrificial layer specifically includes: forming a photoresist on the sacrificial layer, patterning the photoresist, and removing the photoresist in the target region to form the mask layer having the through hole.

Optionally, in the above method for patterning the quantum dot layer provided by the embodiment of the present disclosure, the sequentially forming the front film layer and the sacrificial layer which are stacked on the substrate specifically includes: forming an electron transport layer on the substrate; wherein the electron transport layer is the front film layer, and the electron transport layer is hydrophilic; and forming the sacrificial layer on a side, facing away from the substrate, of the electron transport layer; wherein the sacrificial layer is hydrophobic.

Optionally, in the above method for patterning the quantum dot layer provided by the embodiment of the present disclosure, the sequentially forming the front film layer and the sacrificial layer which are stacked on the substrate specifically includes: forming a cathode on the substrate; wherein the cathode is the front film layer, and the cathode is hydrophilic; and forming the sacrificial layer on a side, facing away from the substrate, of the cathode; wherein the sacrificial layer is hydrophobic.

Optionally, in the above method for patterning the quantum dot layer provided by the embodiment of the present disclosure, after removing the sacrificial layer in the target region, and before laying the quantum dot material, the method further includes: forming an electron transport layer.

Optionally, in the above method for patterning the quantum dot layer provided by the embodiment of the present disclosure, a contact angle of a material of the sacrificial layer with water is greater than 90°.

Optionally, in the above method for patterning the quantum dot layer provided by the embodiment of the present disclosure, the material of the sacrificial layer has a Si—O—Si hydrophobic chain.

Optionally, in the above method for patterning the quantum dot layer provided by the embodiment of the present disclosure, the material of the sacrificial layer includes at least one of: polymethylsilsesquioxane, methacrylamidepolysilsesquioxane, polyphenylsilsesquioxane, polydimethylsiloxane, polyfluorosiloxane or polychlorosiloxane.

Optionally, in the above method for patterning the quantum dot layer provided by the embodiment of the present disclosure, a backbone or a branched chain of the material of the sacrificial layer has a fluorine hydrophobic group of —F or —CF₃.

Optionally, in the above method for patterning the quantum dot layer provided by the embodiment of the present disclosure, the material of the sacrificial layer includes at least one of: fluoropolystyrene or fluoropolyacrylate.

Optionally, in the above method for patterning the quantum dot layer provided by the embodiment of the present disclosure, the etching the sacrificial layer in the target region under the shielding of the mask layer specifically includes: removing the remaining sacrificial layer and the photoresist by solvent soaking or solvent rinsing.

Optionally, in the above method for patterning the quantum dot layer provided by the embodiment of the present disclosure, the patterning the photoresist, and removing the photoresist in the target region specifically includes: shielding the photoresist with a mask, wherein the mask includes a light-transmissive region and a light shielding region, wherein the light-transmissive region corresponds to a retained region to be irradiated by light in the photoresist, and the light shielding region corresponds to the target region; and removing the photoresist in the target region with a solvent.

Optionally, in the above method for patterning the quantum dot layer provided by the embodiment of the present disclosure, the removing the sacrificial layer in the target region specifically includes: etching away the sacrificial layer in the target region by using oxygen plasma.

Optionally, in the above method for patterning the quantum dot layer provided by the embodiment of the present disclosure, the laying the quantum dot material, and curing the quantum dots in the target region specifically includes: laying a quantum dot material with a photosensitive material; and irradiating the quantum dot material in the target region with light of a preset wavelength; wherein under irradiation with the light of the preset wavelength, the photosensitive material or a product of the photosensitive material after the light irradiation reacts with ligands on the surfaces of the quantum dots, so that the ligands are detached from the surfaces of the quantum dots to change a solubility of the quantum dots in the target region, so that the quantum dots in the target region is subjected to coagulation to cure the quantum dots in the target region; or, the laying the quantum dot material, and curing the quantum dots in the target region specifically includes: laying a quantum dot material with crosslinkable ligands on a surface of the quantum dot material; and irradiating the quantum dot material in the target region with light of a preset wavelength, so that quantum dots in the target region are crosslinked so as to cure the quantum dots in the target region.

Optionally, in the above method for patterning the quantum dot layer provided by the embodiment of the present disclosure, a material of the electron transport layer includes ZnO, ZnMgO or ZnAlOx.

### BRIEF DESCRIPTION OF THE DRAWINGS

FIG. 1 is a schematic flow chart of a method for patterning a quantum dot layer according to an embodiment of the present disclosure.

FIG. 2 is a schematic flow chart of yet another method for patterning a quantum dot layer provided by an embodiment of the present disclosure.

FIGS. 3A-3K are schematic structural diagrams in manufacturing steps of the method for patterning the quantum dot layer according to the embodiment of the present disclosure.

FIG. 4 is a schematic flow chart of yet another method for patterning a quantum dot layer provided by an embodiment of the present disclosure.

FIGS. 5A-5J are schematic structural diagrams in manufacturing steps of the method for patterning the quantum dot layer according to the embodiment of the present disclosure.

FIG. 6A is a schematic structural diagram of polymethylsilsesquioxane according to an embodiment of the present disclosure.

FIG. 6B is a schematic structural diagram of methacrylamide polysilsesquioxane according to an embodiment of the present disclosure.

FIG. 6C is a schematic structural diagram of polyphenylsilsesquioxane according to an embodiment of the present disclosure.

FIG. 7 is a schematic diagram of synthesis of the structure shown in FIG. 6C.

FIG. 8A is a schematic structural diagram of fluoropolystyrene according to an embodiment of the present disclosure.

FIG. 8B is a schematic structural diagram of fluoropolyacrylate according to an embodiment of the present disclosure.

FIG. 8C is a schematic structural diagram of yet another fluoropolyacrylate according to an embodiment of the present disclosure.

FIGS. 9A and 9B are schematic diagrams of synthesis of the structure shown in FIG. 8C.

FIG. 10 is a schematic structural diagram of a quantum dot light-emitting device according to an embodiment of the present disclosure.

FIG. 11 is a schematic structural diagram of a quantum dot light-emitting device of an inverted structure according to an embodiment of the present disclosure.

FIG. 12 is a schematic structural diagram of a quantum dot light-emitting device of an upright structure according to an embodiment of the present disclosure.

### DETAILED DESCRIPTION OF THE EMBODIMENTS

In order to make objectives, technical solutions and advantages of the embodiments of the present disclosure clearer, the technical solutions of the embodiments of the present disclosure are described clearly and completely below with reference to the drawings of the embodiments of the present disclosure. Apparently, the described embodiments are some, not all, of the embodiments of the present disclosure. And the embodiments in the present disclosure and features of the embodiments may be combined with each other without conflict. Based on the described embodiments of the present disclosure, all other embodiments obtained by those of ordinary skill in the art without inventive efforts fall within the protection scope of the present disclosure.

Unless otherwise defined, the technical or scientific terms used in the present disclosure shall have the ordinary meaning as understood by those of ordinary skill in the art to which the present disclosure belongs. “Include” or “comprise” and other similar words used in the present disclosure mean that an element or item preceding the word covers elements or items listed behind the word and their equivalents without excluding other elements or items. “Connection” or “connected” and the like are not limited to physical or mechanical connections, but can include electrical connections, whether direct or indirect. “Inner”, “outer”, “upper”, “lower” and the like are only used to indicate a relative positional relationship, and the relative positional relationship may change accordingly when an absolute position of the described object changes.

It should be noted that sizes and shapes of all figures in the drawings do not reflect a true scale and are only intended to illustrate the contents of the present disclosure. And the same or similar reference numerals throughout refer to the same or similar elements or elements having the same or similar function.

A colloidal solution of quantum dots can be patterned by printing, transfer printing, photolithography, etc., but printing equipment is expensive and limited in resolution, and many researchers have done much work in photolithographic patterning in recent years. Some quantum dot film layers are patterned by direct photolithography, i.e., by using a method of crosslinking ligands, ligands for quantum dots are subject to crosslinked and cured under ultraviolet light irradiation, and non-crosslinked moieties can be washed away by a solvent due to high solubility, but this method is prone to color mixing due to residual quantum dots when a full-color device is manufactured.

When a sacrificial layer is used to assist in patterning, in unwanted pixels, quantum dots can be peeled off with the sacrificial layer and a photoresist, which is less prone to color mixing; however, a commonly used material of the sacrificial layer in this method is polyvinylpyrrolidone, which is soluble in water and ethanol and has strong hydrophilicity; for example, for an inverted quantum dot device, prior to manufacturing a patterned quantum dot layer, a sacrificial layer and a photoresist layer can be manufactured on an electron transport layer, or a sacrificial layer and a photoresist layer can be manufactured on a transparent electrode layer, i.e. the sacrificial layer is in direct contact with either the electron transport layer or the transparent electrode layer, and the electron transport layer and the transparent electrode layer have strong hydrophilicity due to the presence of hydroxy usually on the surface of the electron transport layer and the surface of the transparent electrode layer; according to the principle of “like dissolves like”, when both surfaces have the same hydrophilicity or hydrophobicity, the force between the sacrificial layer and the surface of the electron transport layer or between the sacrificial layer and the surface of the transparent electrode layer is strong, making subsequent peeling for the photoresist difficult. Thus, after the sacrificial layer is etched and the quantum dots are deposited, the peeling process for the photoresist typically requires ultrasonic assistance to accelerate the peeling process. During ultrasonic peeling for the photoresist, due to ultrasonic violence, partial detachment of the electron transport layer and the quantum dot film layer may occur, reducing the integrity of the film layers, and causing uneven luminescence of a device. Therefore, solving the affinity between film layers and improving the integrity of the film layers are of great significance for improving the luminous performance of devices.

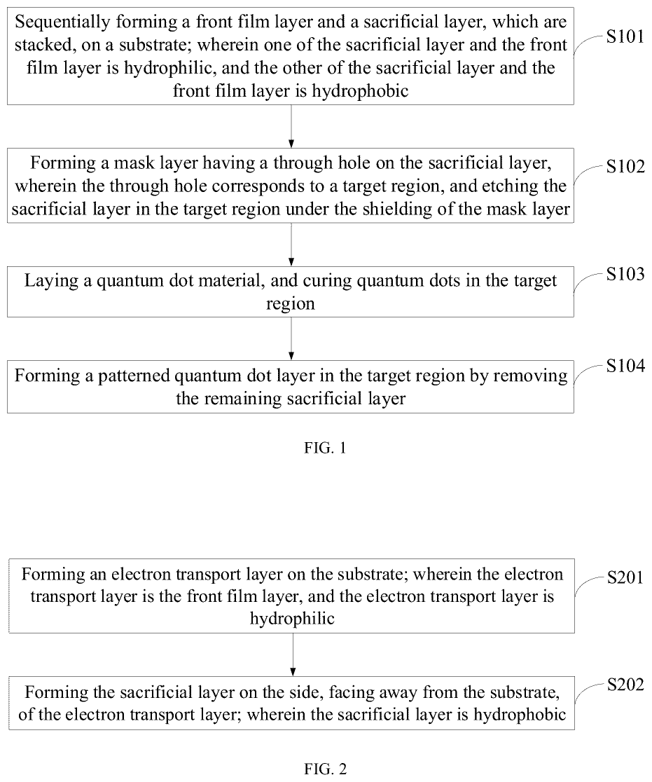

In order to solve the above problems that the peeling process for the photoresist requires ultrasonic assistance to accelerate the peeling process, causing partial detachment of the electron transport layer and the quantum dot film layer, reducing the integrity of the film layers, and causing uneven luminescence of the device, an embodiment of the present disclosure provides a method for patterning a quantum dot layer, as shown in FIG. 1, including: S101, sequentially forming a front film layer and a sacrificial layer, which are stacked, on a substrate; wherein one of the sacrificial layer and the front film layer is hydrophilic, and the other of the sacrificial layer and the front film layer is hydrophobic; S102, forming a mask layer having a through hole on the sacrificial layer, wherein the through hole corresponds to a target region, and etching the sacrificial layer in the target region under the shielding of the mask layer; S103, laying a quantum dot material, and curing quantum dots in the target region; and S104, forming a patterned quantum dot layer in the target region by removing the remaining sacrificial layer.

According to the method for patterning the quantum dot layer provided by the embodiment of the present disclosure, by selecting the front film layer and the sacrificial layer which have opposite hydrophilicity and hydrophilicity, the affinity between the front film layer and the sacrificial layer can be reduced, so that the subsequent peeling for the sacrificial layer and the mask layer becomes easy, the sacrificial layer and the mask layer can be peeled off without adopting an ultrasonic mode, and the integrity of other film layers of the device where the quantum dot layer is located is maintained, thus improving the performance of the device.

In one possible implementation, in the above method for patterning the quantum dot layer provided by the embodiment of the present disclosure, the laying the quantum dot material, and curing the quantum dots in the target region specifically includes: laying the quantum dot material by one or a combination of more of spin coating, blade coating, spray coating, ink jet printing, or electrojet printing.

It can be understood by those skilled in the art that a manner of laying the quantum dot material may not be limited to the manners described above.

In one possible implementation, in the above method for patterning the quantum dot layer provided by the embodiment of the present disclosure, the forming the mask layer having the through hole on the sacrificial layer may specifically include: forming a photoresist on the sacrificial layer, patterning the photoresist, and removing the photoresist in the target region to form the mask layer having the through hole. Since the photoresist requires only exposure development to form a patterned photoresist pattern, the photoresist can be patterned according to the location of the patterned quantum dot layer that needs to be formed, which is simple and convenient to manufacture, and thus, a patterned photoresist is used as the mask layer in the embodiment of the present disclosure.

Of course, the mask layer is also not limited to being formed with the photoresist, for example, the mask layer may be a mask layer having a through hole region manufactured with a quartz material or a metal material.

In particular, the patterned photoresist is used as the mask layer in the embodiment of the present disclosure, since the photoresist needs to be subjected to exposure development to form a patterned region, taking a negative photoresist as an example, the negative photoresist in an exposure region is retained, the negative photoresist in an unexposed region is developed, the retained photoresist may undergo denaturation due to exposure, an acid or base is generally required to clean away the exposed photoresist, while the corrosiveness of the acid or base will destroy the performance of quantum dots, it is therefore necessary to introduce a sacrificial layer before the photoresist, the sacrificial layer can be peeled off by using a common solvent, that is, the sacrificial layer is introduced for better peeling the photoresist, and in the present disclosure, the sacrificial layer has hydrophilicity and hydrophobicity which are opposite to those of the front film layer, so the sacrificial layer and the photoresist can be peeled off without the ultrasonic mode, and the integrity of other film layers of the device where the quantum dot layer is located is maintained, thereby improving the performance of the device.

In the subsequent manufacturing method, the embodiment of the present disclosure adopts a solution of sacrificial layer+photoresist as a mask layer to manufacture the patterned quantum dot layer.

Optionally, quantum dots provided by the embodiment of the present disclosure include, but are not limited to, quantum dots such as CdS, CdSe, ZnSe, InP, PbS, CsPbCl₃, CsPbBr₃, CsPhI₃, CdS/ZnS, CdSe/ZnSe, CdSe/ZnS, ZnSe, InP/ZnS, PbS/ZnS, CsPbCl₃/ZnS, CsPbBr₃/ZnS, and CsPhI₃/ZnS, etc.

Currently, an electroluminescent device can be divided into an electroluminescent device of an upright structure and an electroluminescent device of an inverted structure, which differ in the order in which film layers are manufactured. Specifically, for the upright structure, an anode, a hole injection layer, a hole transport layer, a quantum dot layer, an electron transport layer, and a cathode are sequentially formed on a substrate, and for the inverted structure, an electron transport layer, a quantum dot layer, a hole transport layer, a hole injection layer, and an anode are sequentially formed on a substrate.

It should be noted that the embodiments of the present disclosure mainly describe in detail the method for patterning the quantum dot layer by taking a light-emitting device of an inverted structure as an example, and of course, the embodiments of the present disclosure also apply to a method for patterning a quantum dot layer in an upright structure.

In order to achieve full-color display, the quantum dot layer generally includes patterned quantum dots of different colors, and the embodiments of the present disclosure introduce in detail the method for patterning the nano particle layer provided by the embodiment of the present disclosure in connection with the accompanying drawings by taking the condition that the quantum dot layer includes a first quantum dot layer, a second quantum dot layer, and a third quantum dot layer as an example.

A quantum dot solution is prepared, and by taking InP/ZnS quantum dots as an example, a first quantum dot solution, a second quantum dot solution, and a third quantum dot solution of different colors are prepared, respectively. Specifically, InP/ZnS quantum dots may be formed by, but not limited to, solution phase synthesis, a hydrothermal method, a solvothermal method, and the like.

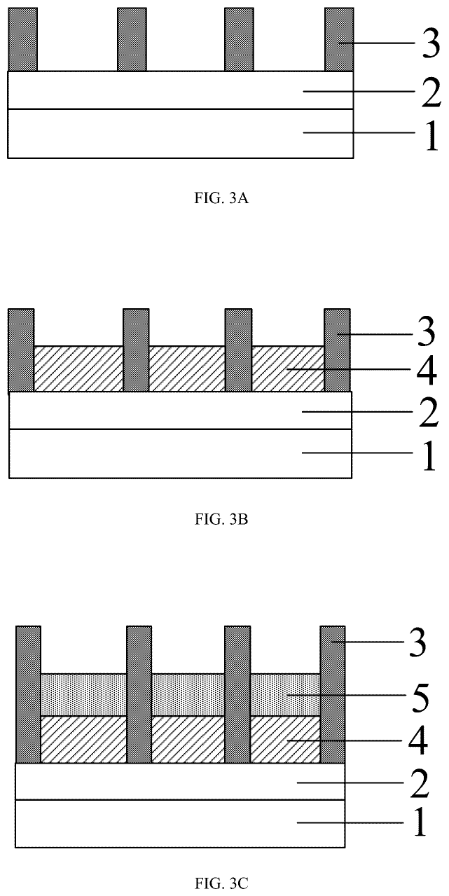

In one possible implementation, in the above method for patterning the quantum dot layer provided by the embodiment of the present disclosure, sequentially forming the front film layer and the sacrificial layer which are stacked on the substrate, as shown in FIG. 2, may specifically include the following.

S201, an electron transport layer is formed on the substrate; wherein the electron transport layer is the front film layer, and the electron transport layer is hydrophilic.

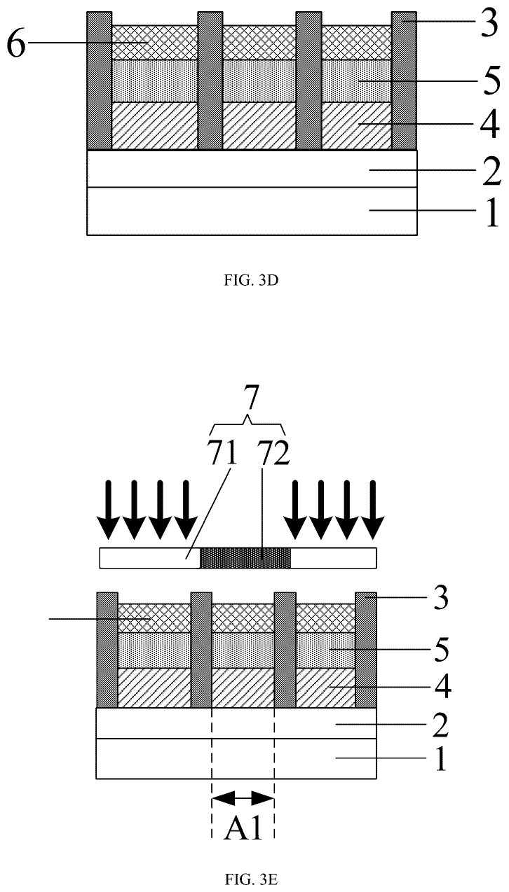

Specifically, as shown in FIG. 3A, a cathode 2 is formed on a substrate 1, wherein a material of the cathode 2 may be a transparent metal oxide electroconductive material, for example, ITO (indium tin oxide), AZO (aluminum doped zinc oxide), IGZO (indium gallium zinc oxide), etc., the substrate 1 on which the cathode 2 is formed is cleaned sequentially with water, ethanol, and acetone for 10 minutes, followed by blow drying with an air gun and treatment with ultraviolet ozone for 10 minutes, and a pixel defining layer 3 is formed on the side, facing away from the substrate 1, of the cathode 2, wherein the pixel defining layer 3 is provided with a plurality of pixel openings exposing the cathode 2; as shown in FIG. 3B, an electron transport layer 4 is formed on the cathode 2 within the pixel openings, wherein a material of the electron transport layer 4 is typically ZnO, for example, a solution of ZnO nanoparticles of 30 mg/ml is spin-coated on the cathode 2, and annealed at 120° C. for 10 minutes; the surface of ZnO will typically have a large amount of hydroxy, and thus, the electron transport layer 4 has strong hydrophilicity.

S202, the sacrificial layer is formed on the side, facing away from the substrate, of the electron transport layer; wherein the sacrificial layer is hydrophobic.

In particular, as shown in FIG. 3C, a sacrificial layer 5 is formed on the side, facing away from the substrate 1, of the electron transport layer 4, and a material with hydrophobicity is selected for the sacrificial layer 5 in order to reduce the affinity between the electron transport layer 4 and the sacrificial layer 5. For example, polyphenylsilsesquioxane having a molar mass greater than 10⁴ g/mol is selected as a material of the sacrificial layer (which is described in detail later), and when a molar mass is greater than 10⁴ g/mol, the polymer is soluble in chlorobenzene but insoluble in xylene. Polyphenylsilsesquioxane is dissolved in chlorobenzene to be prepared into a solution at a concentration of 30 mg/ml, and the polyphenylsilsesquioxane solution is spin coated onto the electron transport layer 4, and left for 10 minutes to be air-dried.

Next, as shown in FIG. 3D, a photoresist 6 is formed on the sacrificial layer 5.

Then, the photoresist is patterned, and the photoresist in the target region is removed; specifically, as shown in FIG. 3E, the photoresist 6 is shielded with a mask 7, wherein the mask 7 includes a light-transmissive region 71 and a light shielding region 72, the light-transmissive region 71 corresponds to a retained region to be irradiated by light in the photoresist 6, and the light shielding region 72 corresponds to a first target region A1 in which first quantum dots are manufactured; and as shown in FIG. 3F, the photoresist in the first target region A1 is removed with a solvent. In particular, since the material of the sacrificial layer used above is insoluble in xylene, the photoresist in the first target region A1 can be developed with xylene.

Next, as shown in FIG. 3G, the sacrificial layer in the first target region A1 is etched under the shielding of the mask layer (the photoresist); and in particular, oxygen plasma may be employed to etch away the sacrificial layer in the first target region A1.

Next, as shown in FIG. 3H, a first quantum dot material 8 is laid on the basis of FIG. 3G, and the first quantum dot material 8 in the first target region A1 is cured.

In particular, curing the first quantum dot material 8 in the first target region A1 may be performed as follows: first laying the first quantum dot material 8 with a photosensitive material, e.g. performing laying after mixing the photosensitive material and the first quantum dot material 8; and then irradiating the first quantum dot material 8 in the first target region A1 with light (e.g. ultraviolet light) of a preset wavelength; wherein under irradiation with the light of the preset wavelength, the photosensitive material or a product of the photosensitive material after light irradiation reacts with ligands on the surfaces of first quantum dots, so that the ligands are detached from the surfaces of the first quantum dots to change the solubility of the first quantum dots in the first target region A1, so that the first quantum dots in the first target region A1 is subjected to coagulation to cure the first quantum dots in the first target region A1.

Further, in specific implementation, in the above method for patterning the quantum dot layer provided by the embodiment of the present disclosure, the photosensitive material can include a photoacid generator, alkenes or alkynes. In particular, when the photosensitive material is a photoacid generator, the photoacid generator generates hydrogen ions under irradiation with ultraviolet light, and the hydrogen ions bind to the ligands on the surfaces of the first quantum dots, so that the ligands are detached from the surfaces of the first quantum dots, the solubility of the first quantum dots without ligands is different from the solubility of the first quantum dots with ligands, so that the first quantum dots without ligands within the first target region A1 can be subjected to coagulation, thereby curing the first quantum dots in the first target region A1. When the photosensitive material is alkenes or alkynes, the alkenes and the alkynes may bind directly to the ligands on the surfaces of the first quantum dots, so that the ligands are detached from the surfaces of the first quantum dots, thereby achieving curing of the first quantum dots in the first target region A1.

In particular, curing the first quantum dot material 8 in the first target region A1 may also be performed as follows: first laying the first quantum dot material 8 with crosslinkable ligands on the surface, wherein ligands on the surfaces of the generally prepared quantum dots do not have a crosslinking function, and the original ligands on the surfaces of the quantum dots can be replaced with a crosslinking agent, thereby preparing the first quantum dot material 8 with the crosslinkable ligands; and then irradiating the first quantum dot material 8 in the first target region A1 with light (e.g. ultraviolet light) of a preset wavelength, and the first quantum dots in the first target region A1 are crosslinked to form a robust crosslinked network structure, so that the first quantum dots in the first target region A1 may be cured.

Next, as shown in FIG. 3I, the remaining sacrificial layer 5 and photoresist 6 are removed, and a patterned first quantum dot layer 81 is formed in the first target region A1. Since the hydrophobicity and hydrophobicity of the sacrificial layer 5 is opposite to those of the electron transport layer 4, the affinity between the sacrificial layer 5 and the electron transport layer 4 is poor, the remaining sacrificial layer 5 and photoresist 6 may thus be removed directly by solvent (which may be chlorobenzene since the sacrificial layer is soluble in chlorobenzene) soaking or solvent (chlorobenzene) rinsing, without the need to employ ultrasound assistance to accelerate the peeling process for the sacrificial layer 5 and the photoresist 6 as in the related art, the peeling for the sacrificial layer 5 and the photoresist 6 in the present disclosure is thus easier, the sacrificial layer 5 and the photoresist 6 can be peeled off without adopting an ultrasonic mode, and the integrity of the first quantum dot layer 81 and the electron transport layer 4 is maintained, thereby improving the performance of the device.

Next, a second quantum dot layer 91 is formed on a second target region A2 by using the same steps as those of FIGS. 3C-3I, as shown in FIG. 3J; wherein the formation of the second quantum dot layer 91 differs from the formation of the first quantum dot layer 81 in that the second quantum dot material is laid.

Finally, a third quantum dot layer 11 is formed on the third target region A3 by using the same steps as those of FIGS. 3C-3I, as shown in FIG. 3K; wherein the formation of the third quantum dot layer 11 differs from the formation of the first quantum dot layer 81 in that the third quantum dot material is laid.

In particular, manufacturing the patterned quantum dot layer shown in FIGS. 3A-3K is illustrated by taking the condition that the front film layer is the electron transport layer 4, i.e., the electron transport layer 4 is first formed on the cathode 2, and then the sacrificial layer 5, the photoresist 6, and the quantum dot material are formed as an example.

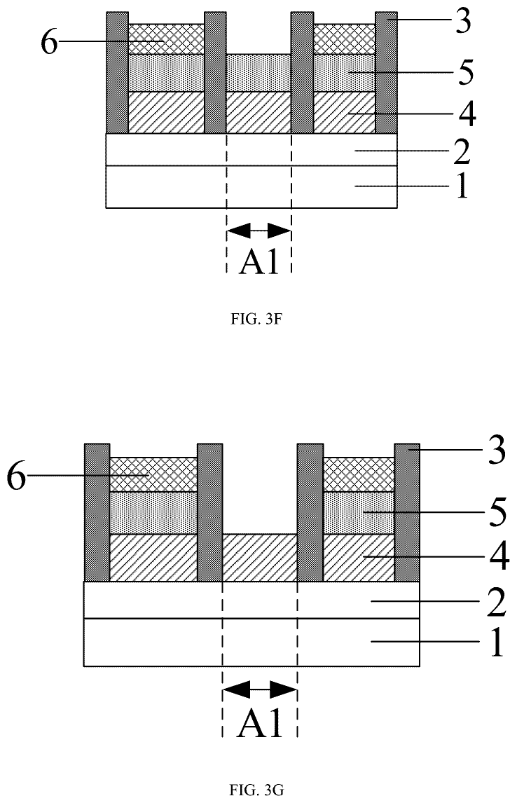

Of course, in yet another possible implementation, in specific implementation, in the above method for patterning the quantum dot layer provided by the embodiment of the present disclosure, sequentially forming the front film layer and the sacrificial layer which are stacked on the substrate, as shown in FIG. 4, may specifically include the following.

S401, a cathode is formed on the substrate; wherein the cathode is the front film layer, and the cathode is hydrophilic.

Specifically, as shown in FIG. 3A, a cathode 2 is formed on a substrate 1, wherein a material of the cathode 2 may be a transparent metal oxide electroconductive material, such as ITO (indium tin oxide), AZO (aluminum doped zinc oxide), IGZO (indium gallium zinc oxide), etc., and the embodiment of the present disclosure takes the condition that the material of the cathode 2 is ITO as an example, the substrate 1 on which the cathode 2 is formed is cleaned sequentially with water, ethanol, and acetone for 10 minutes, followed by blow drying with an air gun and UV ozone treatment for 10 minutes, and then, a pixel defining layer 3 is formed on the side, facing away from the substrate 1, of the cathode 2, wherein the pixel defining layer 3 is provided with a plurality of pixel openings exposing the cathode 2, and since the material of the cathode 2 is the transparent electroconductive material such as ITO, and the surface of ITO typically has a large amount of hydroxy, the cathode 2 has strong hydrophilicity.

S402, the sacrificial layer is formed on the side, facing away from the substrate, of the cathode; wherein the sacrificial layer is hydrophobic.

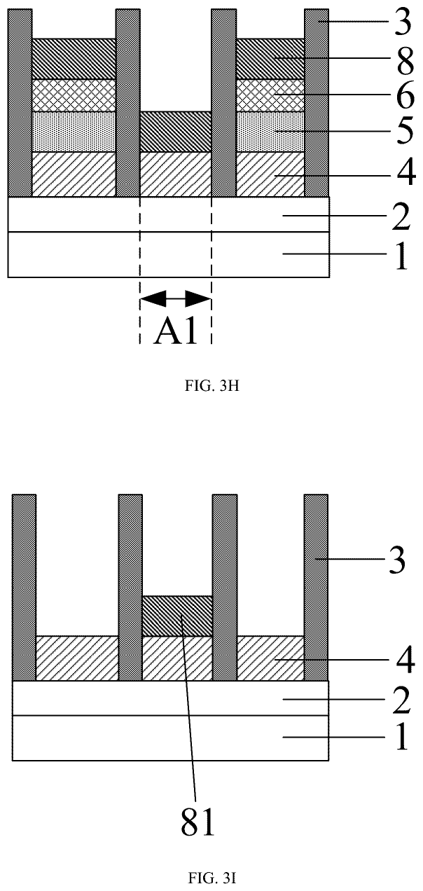

In particular, as shown in FIG. 5A, a sacrificial layer 5 is formed on the side, facing away from the substrate 1, of the cathode 2, and a material with hydrophobicity is selected for the sacrificial layer 5 in order to reduce the affinity between the cathode 2 and the sacrificial layer 5. For example, polyphenylsilsesquioxane having a molar mass greater than 10⁴ g/mol is selected as a material of the sacrificial layer (which is described in detail later), and when a molar mass is greater than 10⁴ g/mol, the polymer is soluble in chlorobenzene but insoluble in xylene. Polyphenylsilsesquioxane is dissolved in chlorobenzene to be prepared into a solution at a concentration of 30 mg/ml, and the polyphenylsilsesquioxane solution is spin coated onto the cathode 2, and left for 10 minutes to be air-dried.

Next, as shown in FIG. 5B, a photoresist 6 is formed on the sacrificial layer 5.

Then, the photoresist is patterned, and the photoresist in the target region is removed; specifically, as shown in FIG. 5C, the photoresist 6 is shielded with a mask 7, wherein the mask 7 includes a light-transmissive region 71 and a light shielding region 72, the light-transmissive region 71 corresponds to a retained region to be irradiated by light in the photoresist 6, and the light shielding region 72 corresponds to a first target region A1 in which first quantum dots are manufactured; and as shown in FIG. 5D, the photoresist in the first target region A1 is removed with a solvent. In particular, since the material of the sacrificial layer used above is insoluble in xylene, the photoresist in the first target region A1 can be developed with xylene.

Next, as shown in FIG. 5E, the sacrificial layer in the first target region A1 is etched under the shielding of the mask layer (the photoresist); and in particular, oxygen plasma may be employed to etch away the sacrificial layer in the first target region A1.

Next, as shown in FIG. 5F, an electron transport layer 4 is formed on the basis of FIG. 5E.

Next, as shown in FIG. 5G, a first quantum dot material 8 is laid on the basis of FIG. 5F, and the first quantum dot material 8 in the first target region A1 is cured. In particular, a manner of curing the first quantum dot material 8 in the first target region A1 can refer to the curing manner described above for the steps of FIG. 3H, which is not repeated here.

Next, as shown in FIG. 5H, the remaining sacrificial layer 5 and the photoresist 6 are removed, and a patterned first quantum dot layer 81 is formed in the first target region A1. Since the hydrophobicity and hydrophobicity of the sacrificial layer 5 are opposite to those of the cathode 2, the affinity between the sacrificial layer 5 and the cathode 2 is poor, the remaining sacrificial layer 5 and photoresist 6 may thus be removed directly by solvent (which may be chlorobenzene since the sacrificial layer is soluble in chlorobenzene) soaking or solvent (chlorobenzene) rinsing, without the need to employ ultrasound assistance to accelerate the peeling process for the sacrificial layer 5 and the photoresist 6 as in the related art, the peeling for the sacrificial layer 5 and the photoresist 6 in the present disclosure is thus easier, the sacrificial layer 5 and the photoresist 6 can be peeled off without adopting an ultrasonic mode, and the integrity of the first quantum dot layer 81 and the electron transport layer 4 is maintained, thereby improving the performance of the device.

In particular, since the electron transport layer 4 in a region other than the first target region A1 is formed on the photoresist 6, the electron transport layer 4 in the region other than the first target region A1 is peeled off, and the first quantum dot layer 81 and the electron transport layer 4 are only formed in the first target region A1.

Next, a second quantum dot layer 91 is formed on a second target region A2 by using the same steps as those of FIGS. 5A-5H, as shown in FIG. 5I; wherein the formation of the second quantum dot layer 91 differs from the formation of the first quantum dot layer 81 in that the second quantum dot material is laid.

In particular, in the process of manufacturing the second quantum dot layer 91, since the electron transport layer 4 in a region other than the second target region A2 is formed on the photoresist 6, the electron transport layer 4 in the region other than the second target region A2 is peeled off, and the second quantum dot layer 91 and the electron transport layer 4 are only formed in the second target region A2.

In particular, in the process of manufacturing the second quantum dot layer 91, since the sacrificial layer formed again may be in contact with the first quantum dot layer, during peeling for the sacrificial layer and the photoresist with a solvent, the solvent selected only dissolves the sacrificial layer but does not dissolve the first quantum dot layer to prevent loss of the manufactured first quantum dot layer.

Finally, a third quantum dot layer 11 is formed on the third target region A3 by using the same steps as those of FIGS. 5A-5H, as shown in FIG. 5J; wherein the formation of the third quantum dot layer 11 differs from the formation of the first quantum dot layer 81 in that the third quantum dot material is laid.

Specifically, in the process of manufacturing the third quantum dot layer 11, since the electron transport layer 4 in a region other than the third target region A3 is formed on the photoresist 6, the electron transport layer 4 in the region other than the third target region A3 is peeled off, the third quantum dot layer 91 and the electron transport layer 4 are only formed in the third target region A3.

In particular, in the process of manufacturing the third quantum dot layer 11, since the sacrificial layer formed again may be in contact with the second quantum dot layer, during peeling for the sacrificial layer and the photoresist with a solvent, the solvent selected may only dissolve the sacrificial layer but does not dissolve the second quantum dot layer to prevent loss of the manufactured second quantum dot layer.

The patterned quantum dot layer can thus be formed either in the manner shown in FIGS. 3A-3K or in FIGS. 5A-5J.

It should be noted that in FIGS. 3A-3K, the electron transport layer 4 is first formed, and then the sacrificial layer 5 is formed, and in FIGS. 5A-5J, the sacrificial layer 5 is first formed, and then the electron transport layer 4 is formed, wherein the electron transport layer 4 is typically formed by sputtering, or coating with a material, i.e., nanoparticles, a sol-gel method, or the like, of the electron transport layer. When the electron transport layer is manufactured by using the sol-gel method, materials for forming the electron transport layer 4 may be mixed to form a sol, the sol is spin coated, and high temperature annealing treatment is performed to remove the solvent to form the electron transport layer 4, since the temperature of the high temperature annealing treatment is above 180° C., while a material of the sacrificial layer 5 is not resistant to high temperature, if the method of first forming the sacrificial layer 5, and then forming the electron transport layer 4 in FIGS. 5A-5J is used, the electron transport layer 4 may not be formed by using the sol-gel method, i.e. the method for manufacturing the electron transport layer 4 is limited, so when the electron transport layer is manufactured by using the sol-gel method, the patterned quantum dot layer is preferably manufactured by using the method of first forming the electron transport layer 4, and then forming the sacrificial layer 5 in FIGS. 3A-3K.

In specific implementation, in the embodiments of the present disclosure, the color of light emitted by the first quantum dot layer, the color of light emitted by the second quantum dot layer, and the color of light emitted by the third quantum dot layer are red, green, and blue, respectively, and thus, in the embodiments of the present disclosure, the patterning process of full-color quantum dots is completed by the above patterning method. In the embodiments of the present disclosure, the patterned quantum dot layer is formed in the sacrificial layer assisted manner, in the process of peeling the sacrificial layer and the photoresist, the sacrificial layer and the photoresist can be peeled off without an ultrasonic process, and the integrity of the quantum dot layer and the electron transport layer is maintained, thereby improving the performance of the device.

Further, in specific implementation, in the above method for patterning the quantum dot layer provided by the embodiment of the present disclosure, as shown in FIGS. 3C and 5A, a contact angle of a material of the sacrificial layer 5 with water is greater than 90°, thus the material of the sacrificial layer 5 is a highly hydrophobic material, i.e. the affinity between the material of the sacrificial layer 5 and the electron transport layer 4 or the cathode 2 is low, and the photoresist 6 and the sacrificial layer 5 may be peeled off by only soaking or rinsing without adopting the ultrasonic process during the subsequent peeling process of the photoresist and the sacrificial layer.

In particular, when the patterned quantum dot layer is formed in the manner shown in FIGS. 3A-3K or in FIGS. 5A-5J, a specific material of the sacrificial layer 5 is not specifically introduced, it is only disclosed that the hydrophilicity and hydrophobicity of the material of the sacrificial layer 5 are opposite to those of the material of the electron transport layer 4 and the material of the cathode 2, since the material of the electron transport layer 4 is typically ZnO, and the material of the cathode 2 is typically a metal oxide transparent electroconductive material such as ITO, IGZO, AZO, etc., for example, the material of the cathode 2 is ITO, both surfaces of ZnO and ITO have a large amount of hydroxy, ZnO and ITO are hydrophilic, and thus a hydrophobic material of the sacrificial layer 5 is employed.

Further, in specific implementation, in the above method for patterning the quantum dot layer provided by the embodiment of the present disclosure, the material of the sacrificial layer may be a material having a Si—O—Si hydrophobic chain.

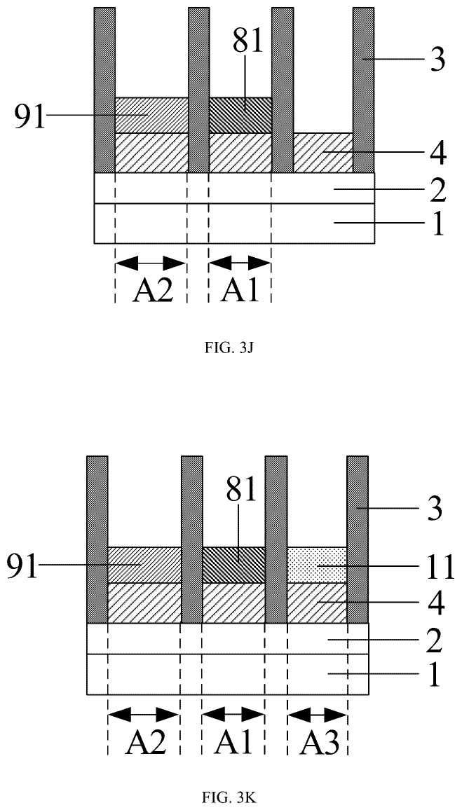

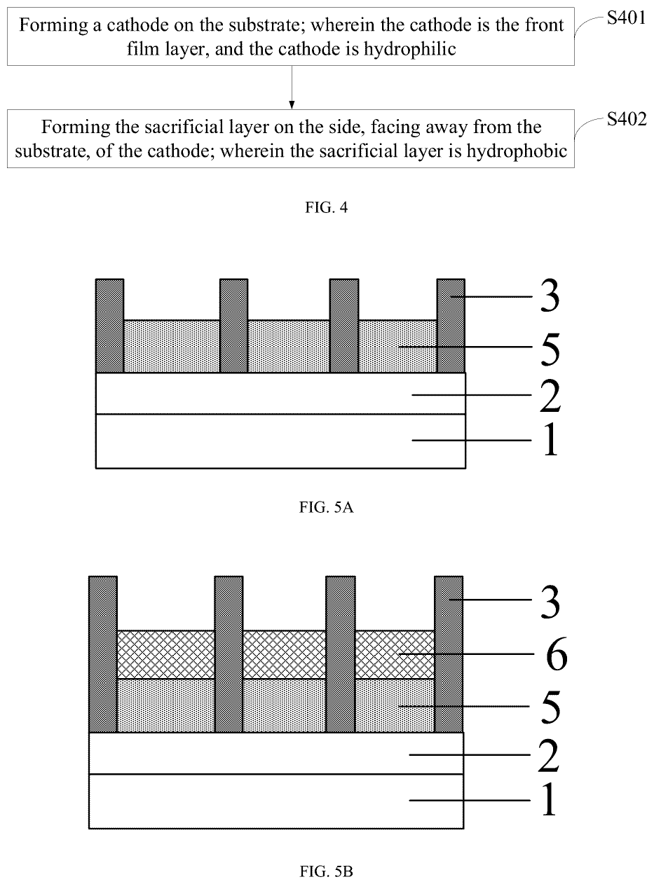

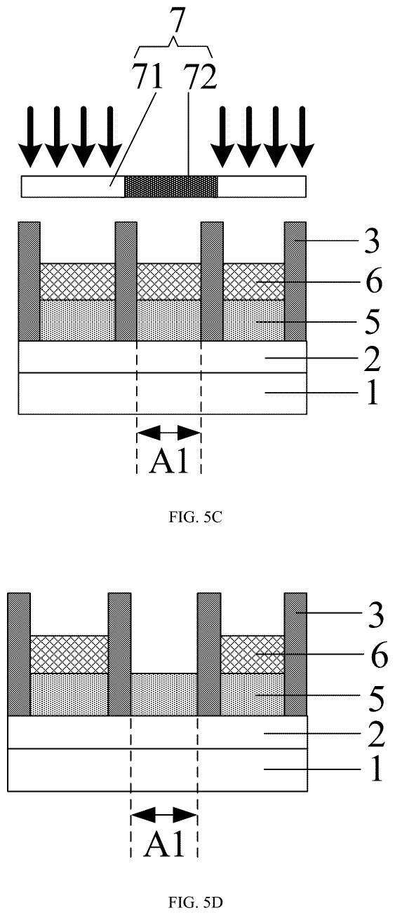

Further, in specific implementation, in the above method for patterning the quantum dot layer provided by the embodiment of the present disclosure, the material of the sacrificial layer includes, but is not limited to, at least one of: polymethylsilsesquioxane, methacrylamidepolysilsesquioxane, polyphenylsilsesquioxane, polydimethylsiloxane, polyfluorosiloxane or poly chlorosiloxane. For example, a structural formula of polymethylsilsesquioxane is shown in FIG. 6A, a structural formula of methacrylamidepolysilsesquioxane is shown in FIG. 6B, and a structural formula of polyphenylsilsesquioxane is shown in FIG. 6C; and these materials each include Si—O—Si hydrophobic chains and have a lower affinity with the electron transport layer or the cathode, making it easy for subsequent peeling for the photoresist.

It should be noted that since Si is a tetravalent element, * in FIGS. 6A-6C indicates that Si can also be connected to other groups, such as alkane groups, methoxy, ester groups, and the like.

Specifically, by taking the condition that when the patterned quantum dot layer is formed in the manner shown in FIGS. 3A-3K or in FIGS. 5A-5J, the material of the sacrificial layer 5 employed is polyphenylsilsesquioxane shown in FIG. 6C as an example, a method for preparing polyphenylsilsesquioxane is as follows.

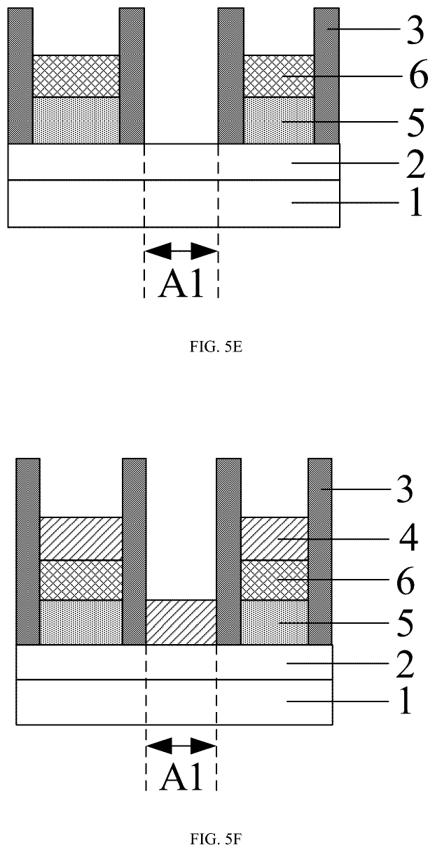

By using phenyltriethoxysilane as a raw material, phenyltriethoxysilane, ethanol, and 0.01% hydrochloric acid are mixed, and stirred in a flask for 8 hours or more, and phenyltriethoxysilane is first subjected to a hydrolysis reaction to obtain phenylsilanol; and then, 4% ammonia is added, and stirring is continued to be performed for 24 hours, wherein in this step, phenylsilsesquioxane is obtained by dehydration condensation of a silanol bond, and a polyphenylsilsesquioxane polymer can be formed by a condensation reaction between multiple molecules under the action of ammonia, polyphenylsilsesquioxane is separated out by centrifugation, and excess ions are washed off with water, followed by oven drying for standby application. A schematic diagram of a synthesis process of polyphenylsilsesquioxane is shown in FIG. 7.

It should be noted that the embodiments of the present disclosure include, but are not limited to, the sacrificial layer materials with Si—O—Si hydrophobic chains listed above.

Further, in specific implementation, in the above method for patterning the quantum dot layer provided by the embodiment of the present disclosure, a backbone or a branched chain of the material of the sacrificial layer can have a fluorine hydrophobic group of —F or —CF₃.

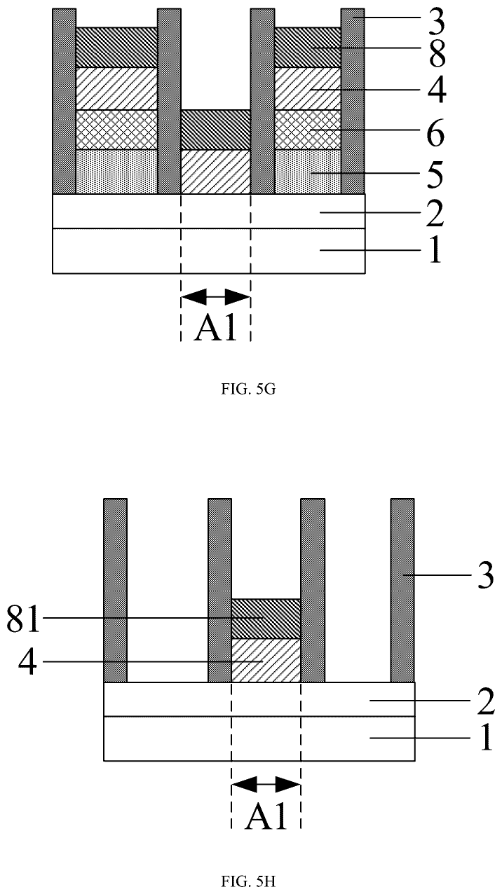

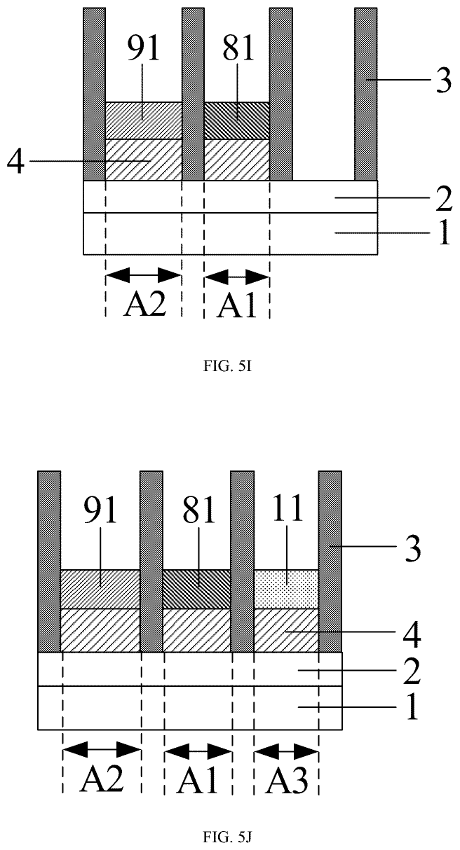

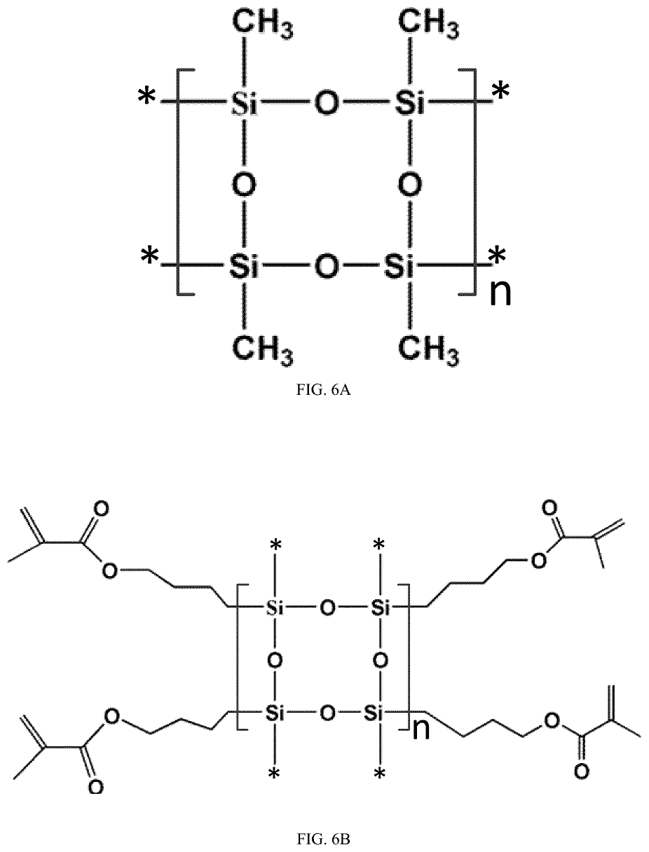

Further, in specific implementation, in the above method for patterning the quantum dot layer provided by the embodiment of the present disclosure, the material of the sacrificial layer includes, but is not limited to, at least one of: fluoropolystyrene or fluoropolyacrylate. For example, a structural formula of fluoropolystyrene is shown in FIG. 8A, and a structural formula of fluoropolyacrylate can be shown in FIG. 8B and FIG. 8C, wherein in FIG. 8B, a backbone has a substituent —F, and in FIG. 8C, a branched chain has a substituent —CF₃. In addition, in FIG. 8B, R may be an alkane group, methoxy, an ester group, or the like, and R′ may be an alkane group or the like. These materials each include a fluorine hydrophobic group and have a lower affinity with the electron transport layer or the cathode, making it easy for subsequent peeling of the photoresist.

It should be noted that since C is a tetravalent element, * in FIGS. 8A-8C indicates that C can also be connected to other groups, such as alkane groups, methoxy, ester groups, and the like.

Specifically, by taking the condition that when the patterned quantum dot layer is formed in the manner shown in FIGS. 3A-3K or in FIGS. 5A-5J, the material of the sacrificial layer 5 employed is fluoropolyacrylate shown in FIG. 8C as an example, a method for preparing fluoropolyacrylate is as follows.

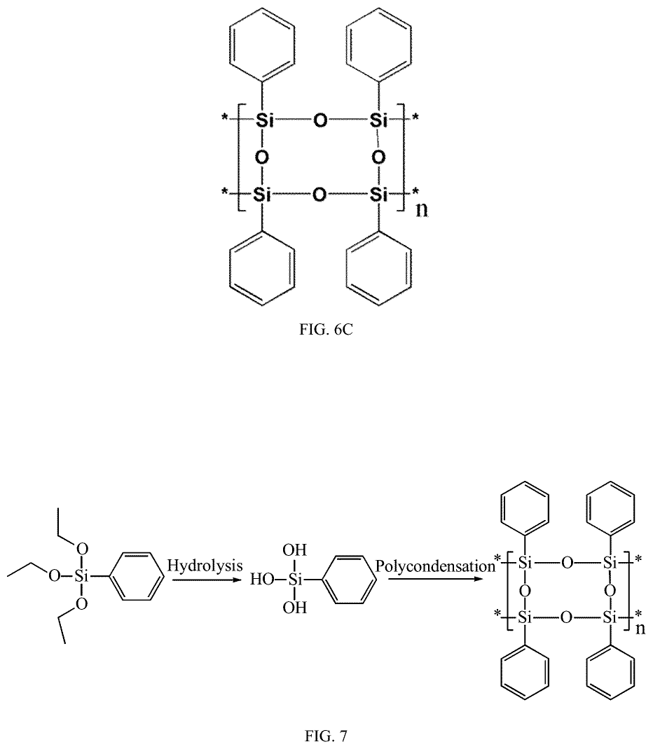

Polyethylene glycol acrylate is obtained through esterification by using benzenesulfonic acid as a catalyst, and using acrylic acid and polyethylene glycol as reaction raw materials, as shown in FIG. 9A. Polyethylene glycol acrylate and hexafluorobutyl methacrylate are subjected to polymerization by using azobisisobutyronitrile as an initiator to finally obtain a fluoropolyacrylate polymer, as shown in FIG. 9B.

It should be noted that the embodiments of the present disclosure include, but are not limited to, the sacrificial layer materials listed above with the backbone or branched chain having the fluorine hydrophobic group of —F or —CF₃.

Further, in specific implementation, in the above method for patterning the quantum dot layer provided by the embodiment of the present disclosure, a material of the electron transport layer includes ZnO, ZnMgO, or ZnAlOx. These electron transport layer materials have the characteristic of having a large quantity of hydroxy on the surfaces, and thus have strong hydrophilicity.

It should be noted that the embodiments of the present disclosure are described by taking the condition that the electron transport material is hydrophilic as an example, of course, in specific implementation, the electron transport material may also have hydrophobicity, and for manufacturing a device by using the electron transport material having hydrophobicity, the material of the aforementioned sacrificial layer may employ a corresponding material having hydrophilicity to reduce the bonding force at the interface of the two for subsequent peeling for the photoresist.

It should be noted that the embodiments of the present disclosure are described by taking a device of an inverted structure as an example, when an upright structure is employed, the aforementioned front film layer may be either a hole transport layer or an anode, so the material of the sacrificial layer is selected as long as its hydrophilicity and hydrophobicity are opposite to the hydrophilicity and hydrophobicity of the hole transport layer or the anode, and a specific quantum dot layer patterning process is similar to the aforementioned manufacturing method for the device of the inverted structure, which is not repeated here.

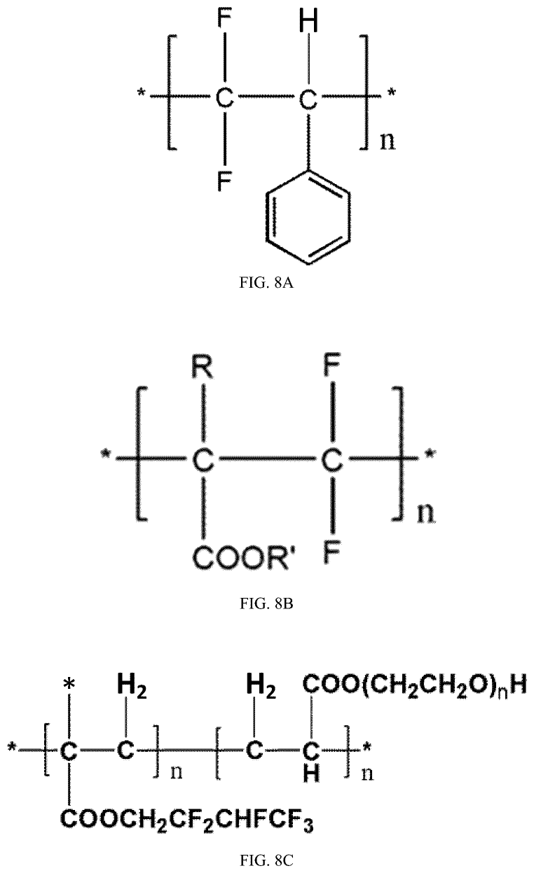

Based on the same inventive concept, an embodiment of the present disclosure also provides a quantum dot light-emitting device, as shown in FIG. 10, including a cathode 2, quantum dot layers (81, 91, 11), and an anode 10 which are sequentially stacked, wherein the quantum dot layers (81, 91, 11) are quantum dot layers formed by using the foregoing method for patterning the quantum dot layer.

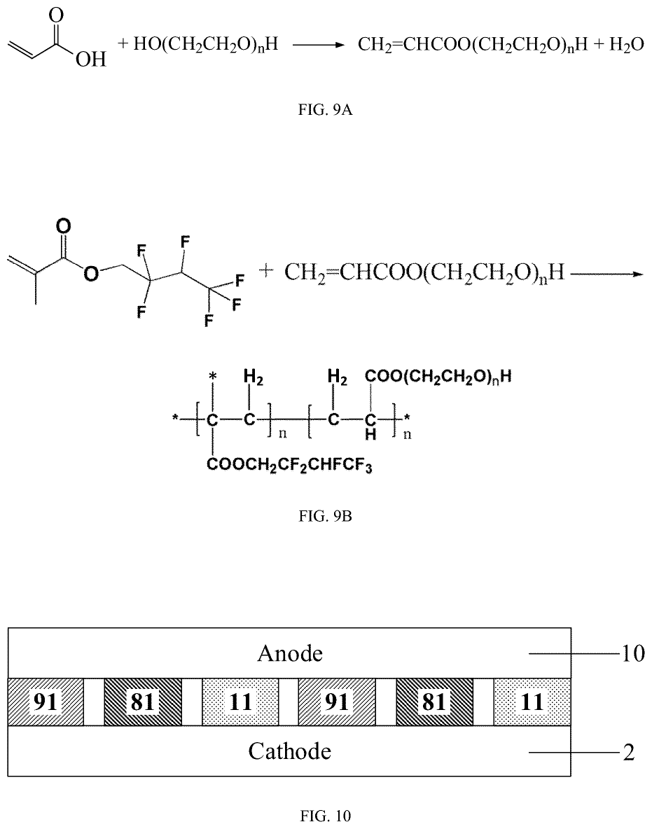

In specific implementation, the above quantum dot light-emitting device provided by the embodiment of the present disclosure, as shown in FIG. 11, specifically includes a substrate 1, and a cathode 2, an electron transport layer 4, quantum dot layers (81, 91, 11), a hole transport layer 12, a hole injection layer 13, and an anode 10 which are sequentially stacked on the substrate 1.

It should be noted that a principle that an electroluminescent device emits light is as follows: holes at an anode and electrons at a cathode are transported to a light-emitting layer (the quantum dot layer) to be recombinated for emitting light, due to the difference in energy level barriers between the anode and the light-emitting layer as well as between the cathode and the light-emitting layer, the electron transport and hole transport is difficult and the transport rates and quantities of holes and electrons are also very different, in order to balance the concentration of electrons and holes, a hole injection layer and a hole transport layer are therefore generally arranged between the light-emitting layer (the quantum dot layer) and the anode, and an electron transport layer is arranged between the light-emitting layer (the quantum dot layer) and the cathode, and of course, in specific implementation, it is possible to select which layers are needed according to actual needs.

In particular, the substrate provided by the embodiment of the present disclosure can include a base substrate, a driving circuit located on the base substrate, and structures such as a passivation layer and a flat layer located above the driving circuit.

In specific implementation, the embodiment of the present disclosure takes an inverted structure an example, and the embodiment of the present disclosure further includes an encapsulation process, a cutting process, and a bonding process of the quantum dot light-emitting device after the anode is manufactured, and all the processes are the same as those in the prior art, which are not repeated here.

A method for manufacturing the quantum dot light-emitting device of the inverted structure according to the embodiment of the present disclosure is briefly described below by way of a specific embodiment. Specifically, manufacturing methods of film layers in the quantum dot light-emitting device include, but are not limited to, one or more of a spin coating method, an evaporation method, a chemical vapor deposition method, a physical vapor deposition method, a magnetron sputtering method, and the like.

As shown in FIG. 11, the cathode 2 is formed on the substrate 1, wherein a method for manufacturing the cathode 2 is the same as that in the prior art, which is not described in detail here; next, the electron transport layer 4 is formed on the cathode 2, wherein a method for manufacturing the electron transport layer 4 is the same as that in the prior art, which is not described in detail here; next, quantum dot layers including the first quantum dot layer 81, the second quantum dot layer 91, and the third quantum dot layer 11 are formed on the electron transport layer 4 by using the method for patterning the quantum dot layer described above; and then, the hole transport layer 12, the hole injection layer 13, and the anode 10 are sequentially manufactured on the quantum dot layers, wherein methods for manufacturing the hole transport layer 12, the hole injection layer 13 and the anode 10 are the same as those in the prior art, which are not described in detail here.

Encapsulation is performed after the manufacture of the above film layers is completed, completing the manufacture of the quantum dot light-emitting device of the inverted structure in the embodiment of the present disclosure.

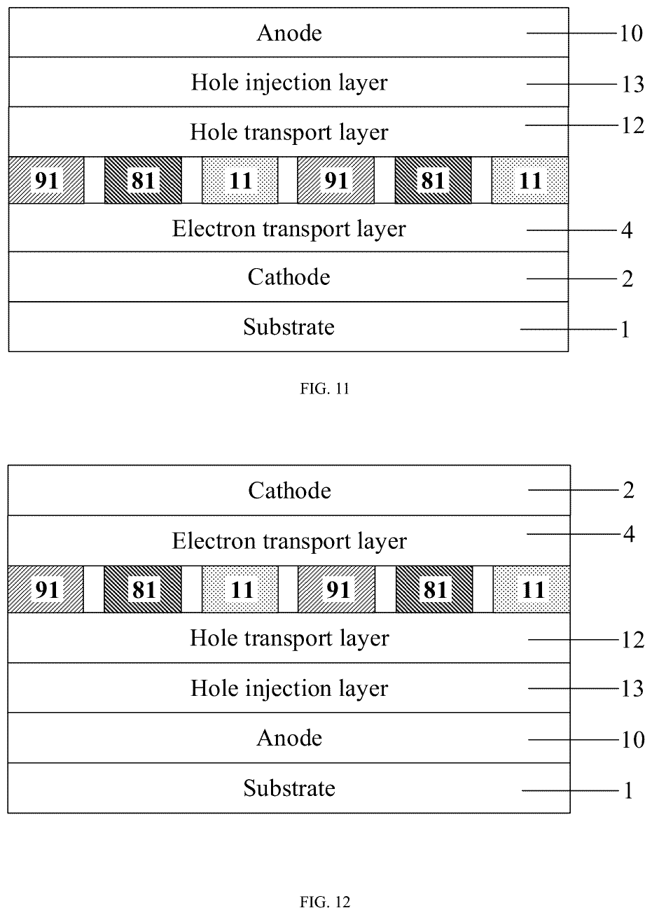

It should be noted that in the embodiments of the present disclosure, in FIG. 11, by taking the quantum dot light-emitting device of the inverted structure an example, its manufacturing method is illustrated, of course, the quantum dot light-emitting device may also be of an upright structure, as shown in FIG. 12, when the quantum dot light-emitting device is of an upright structure, the difference from manufacture of the inverted structure is that in the upright structure, the anode 10, the hole injection layer 13, the hole transport layer 12, the quantum dot layers (81, 91, 11), the electron transport layer 4, and the cathode 2 are sequentially formed on the substrate 1, which is not described in detail here. Specifically, a specific manufacture process of the quantum dot light-emitting device of the upright structure can refer to the above method for manufacturing the quantum dot light-emitting device of the inverted structure, only that the order of manufacture of the film layers is changed, which is not described in detail here.

In the present disclosure, there are no restrictions on the light-emitting type of the quantum dot light-emitting device, for example, being not limited to bottom light emission or top light emission.

In specific implementation, the quantum dot light-emitting device provided by the embodiment of the present disclosure also includes other functional film layers well known to those skilled in the art, which is not described in detail here.

Based on the same disclosed concept, an embodiment of the present disclosure also provides a display device, including the above quantum dot light-emitting device provided by the embodiment of the present disclosure. The display device may be: any product or component with a display function, such as a mobile phone, a tablet computer, a television, a display, a notebook computer, a digital photo frame, and a navigator. Other essential components of the display device should be understood by those of ordinary skill in the art, and will not be repeated here, nor should they be regarded as a limitation to the present disclosure. The principle of solving the problem of the display device is similar to that of the aforementioned quantum dot light-emitting device, so the implementation of the display device can refer to the implementation of the aforementioned quantum dot light-emitting device, and repetitions are omitted here.

According to the method for patterning the quantum dot layer provided by the embodiment of the present disclosure, by selecting the front film layer and the sacrificial layer which have opposite hydrophilicity and hydrophilicity, the affinity between the front film layer and the sacrificial layer can be reduced, so that the subsequent peeling for the sacrificial layer and the photoresist becomes easy, the sacrificial layer and the photoresist can be peeled off without adopting the ultrasonic mode, and the integrity of other film layers of the device where the quantum dot layer is located is maintained, thus improving the performance of the device.

Although preferred embodiments of the present disclosure have been described, those skilled in the art can make additional changes and modifications to these embodiments once they know the basic inventive concepts. Therefore, the appended claims are intended to be explained as including the preferred embodiments and all changes and modifications falling within the scope of the present disclosure.

Obviously, those skilled in the art can make various changes and modifications to the embodiments of the present disclosure without departing from the spirit and scope of the embodiments of the present disclosure. Thus, if these changes and modifications of the embodiments of the present disclosure fall within the scope of the claims of the present disclosure and their equivalents, the present disclosure is also intended to include these changes and modifications.

1. A method for patterning a quantum dot layer, comprising:
sequentially forming a front film layer and a sacrificial layer, which are stacked, on a substrate; wherein one of the sacrificial layer and the front film layer is hydrophilic, and the other of the sacrificial layer and the front film layer is hydrophobic;
forming a mask layer having a through hole on the sacrificial layer, wherein the through hole corresponds to a target region, and etching the sacrificial layer in the target region under the shielding of the mask layer;
laying a quantum dot material, and curing quantum dots in the target region; and
forming a patterned quantum dot layer in the target region by removing a remaining sacrificial layer.

2. The method for patterning the quantum dot layer according to claim 1, wherein the forming the mask layer having the through hole on the sacrificial layer specifically comprises:
forming a photoresist on the sacrificial layer, patterning the photoresist, and removing the photoresist in the target region to form the mask layer having the through hole.

3. The method for patterning the quantum dot layer according to claim 1, wherein the sequentially forming the front film layer and the sacrificial layer, which are stacked, on the substrate specifically comprises:
forming an electron transport layer on the substrate; wherein the electron transport layer is the front film layer, and the electron transport layer is hydrophilic; and
forming the sacrificial layer on a side, facing away from the substrate, of the electron transport layer; wherein the sacrificial layer is hydrophobic.

4. The method for patterning the quantum dot layer according to claim 1, wherein the sequentially forming the front film layer and the sacrificial layer, which are stacked, on the substrate specifically comprises:
forming a cathode on the substrate; wherein the cathode is the front film layer, and the cathode is hydrophilic; and
forming the sacrificial layer on a side, facing away from the substrate, of the cathode; wherein the sacrificial layer is hydrophobic.

5. The method for patterning the quantum dot layer according to claim 4, wherein after removing the sacrificial layer in the target region and before laying the quantum dot material, the method further comprises:
forming an electron transport layer.

6. The method for patterning the quantum dot layer according to claim 3, wherein a contact angle of a material of the sacrificial layer with water is greater than 90°.

7. The method for patterning the quantum dot layer according to claim 6, wherein the material of the sacrificial layer has a Si—O—Si hydrophobic chain.

8. The method for patterning the quantum dot layer according to claim 7, wherein the material of the sacrificial layer comprises at least one of: polymethylsilsesquioxane, methacrylamidepolysilsesquioxane, polyphenylsilsesquioxane, polydimethylsiloxane, polyfluorosiloxane or polychlorosiloxane.

9. The method for patterning the quantum dot layer according to claim 6, wherein a backbone or a branched chain of the material of the sacrificial layer has a fluorine hydrophobic group of —F or —CF₃.

10. The method for patterning the quantum dot layer according to claim 9, wherein the material of the sacrificial layer comprises at least one of: fluoropolystyrene or fluoropolyacrylate.

11. The method for patterning the quantum dot layer according to claim 1, wherein the removing the remaining sacrificial layer specifically comprises:
removing the remaining sacrificial layer by solvent soaking or solvent rinsing.

12. The method for patterning the quantum dot layer according to claim 2, wherein the patterning the photoresist, and removing the photoresist in the target region specifically comprises:
shielding the photoresist with a mask, wherein the mask comprises a light-transmissive region and a light shielding region, wherein the light-transmissive region corresponds to a retained region to be irradiated by light in the photoresist, and the light shielding region corresponds to the target region; and
removing the photoresist in the target region with a solvent.

13. The method for patterning the quantum dot layer according to claim 1, wherein the etching the sacrificial layer in the target region under the shielding of the mask layer specifically comprises:
etching away the sacrificial layer in the target region by using oxygen plasma.

14. The method for patterning the quantum dot layer according to claim 1, wherein the laying the quantum dot material, and curing quantum dots in the target region specifically comprises:
laying a quantum dot material with a photosensitive material; and
irradiating the quantum dot material in the target region with light of a preset wavelength; wherein under irradiation with the light of the preset wavelength, the photosensitive material or a product of the photosensitive material after the light irradiation reacts with ligands on the surfaces of the quantum dots, so that the ligands are detached from the surfaces of the quantum dots to change a solubility of the quantum dots in the target region, so that the quantum dots in the target region is subjected to coagulation to cure the quantum dots in the target region;
or,
the laying the quantum dot material, and curing the quantum dots in the target region specifically comprises:
laying a quantum dot material with crosslinkable ligands on a surface of the quantum dot material; and
irradiating the quantum dot material in the target region with light of a preset wavelength, so that quantum dots in the target region are crosslinked so as to cure the quantum dots in the target region.

15. The method for patterning the quantum dot layer according to claim 3, wherein a material of the electron transport layer comprises ZnO, ZnMgO or ZnAlOx.

16. The method for patterning the quantum dot layer according to claim 4, wherein a contact angle of a material of the sacrificial layer with water is greater than 90°.

17. The method for patterning the quantum dot layer according to claim 5, wherein a contact angle of a material of the sacrificial layer with water is greater than 90°.

18. The method for patterning the quantum dot layer according to claim 4, wherein a material of the electron transport layer comprises ZnO, ZnMgO or ZnAlOx.

19. The method for patterning the quantum dot layer according to claim 5, wherein a material of the electron transport layer comprises ZnO, ZnMgO or ZnAlOx.

20. The method for patterning the quantum dot layer according to claim 2, wherein a material of the electron transport layer comprises ZnO, ZnMgO or ZnAlOx.
